(19) United States
(12) Patent Application Publication
(10) Pub. No.: US 2010/0247748 A1
(43) Pub. Date: Sep. 30, 2010

(54) METHOD FOR FORMING COATING FILM AND METHOD FOR MANUFACTURING PIEZOELECTRIC ELEMENT

(75) Inventor: Yoichi NODA, Fujimi-machi (JP)

Correspondence Address: GLOBAL IP COUNSELORS, LLP, 1233 20TH STREET, NW, SUITE 700, WASHINGTON, DC, 20036-2680, US

(73) Assignee: SEIKO EPSON CORPORATION, Tokyo (JP)

(21) Appl. No.: 12/724,906

(22) Filed: Mar. 16, 2010

(30) Foreign Application Priority Data
Mar. 26, 2009 (JP) 2009-077821

(51) Int. Cl. H01L 41/22; B05D 1/36

(52) U.S. Cl. 427/100; 427/402

(57) ABSTRACT

A method for forming a coating film on an object having a top surface, a side surface, and a corner where the top and side surfaces intersect, includes discharging droplets of coating forming material from a nozzle to deposit the droplets on the corner of the object to form a first coating film on the corner, and immersing the object in an immersion coating liquid after the first coating film is formed on the corner of the object to form a second coating film on the top and side surfaces of the object and on the first coating film.

### CROSS-REFERENCE TO RELATED APPLICATIONS

This application claims priority to Japanese Patent Application No. 2009-077821 filed on Mar. 26, 2009. The entire disclosure of Japanese Patent Application No. 2009-077821 is hereby incorporated herein by reference.

### BACKGROUND

1. Technical Field

The present invention relates to a method for forming a coating film and a method for manufacturing a piezoelectric element.

2. Related Art

In conventional practice, the following method is known as a method for forming an electrode on the surface of a piezoelectric substrate made of crystal or another piezoelectric material. Specifically, first, a metal film for forming an electrode is formed by sputtering on a piezoelectric substrate. Next, the metal film is coated with a resist (photoresist), and a resist mask is formed in the shape of the electrode by patterning (lithographic exposure•image development). After the metal film is etched via the resist mask, the resist mask is removed, thereby forming an electrode on the piezoelectric substrate.

Spray coating (see Japanese Laid-Open Patent Application Publication No. 2004-87934), dipping, and other methods are known as methods for coating a metal film with a resist (methods for forming a coating film). Of these examples, spray coating is a method for coating the surface of a metal film with a resist by using air currents to blow a resist in mist form onto a piezoelectric substrate. One dipping method is a method for coating the surface of a metal film with a resist by immersing a piezoelectric substrate in a resist liquid filled in a container.

However, in both these spray coating and dipping methods, a force (surface tension) acts on the resist coated over the metal film so as to reduce the surface area of the resist to a minimum. Therefore, in a resist film formed by drying the coated resist, the portions corresponding to the corners of the piezoelectric substrate are too thin to exhibit the function of a resist mask. As a result, when the metal film is etched via the resist mask formed from the resist film, the metal film is unintentionally removed in the portions corresponding to the corners of the piezoelectric substrate (i.e., the portions where the resist mask is thin), and problems with short-circuiting and wire snapping occur.

### SUMMARY

An object of the present invention is to provide a method for forming a coating film whereby a coating film can be formed in a simple manner on an object, and the thickness can be increased in the portions of the coating film corresponding to the corners of the object; also to provide a method for manufacturing a piezoelectric element whereby a highly reliable piezoelectric element can be manufactured in a simple manner by using this method for forming a coating film.

These objects are achieved by aspects of the present invention described below.

A method according to a first aspect is a method for forming a coating film on an object having a top surface, a side surface, and a corner where the top and side surfaces intersect. The method includes discharging droplets of coating forming material from a nozzle to deposit the droplets on the corner of the object to form a first coating film on the corner, and immersing the object in an immersion coating liquid after the first coating film is formed on the corner of the object to form a second coating film on the top and side surfaces of the object and on the first coating film.

It is thereby possible to form a coating film in a simple manner on an object, and to increase the film thickness of the coating film in the portions corresponding to the corners of the object. Since the first coating film is first formed on the corners of the object by a discharge method, the corners of the coating film are exposed, it is therefore easy to perceive the positions of the corners, and the first coating film can be formed more accurately on the corners. Since the second coating film is formed by immersion on the surface of the object and the first coating film after the first coating film has been formed, a coating film (an aggregate of the first and second coating films) having a smooth surface can be formed.

In the method for forming a coating film as described above, the discharging of the droplets preferably includes selectively forming the first coating film on a prescribed portion of the corner.

It is thereby possible to prevent the first coating film from being formed on unnecessary portions, to reduce the amount of time for performing the first coating film formation step, and to reduce the amount of droplets used.

In the method for forming a coating film as described above, the discharging of the droplets preferably includes discharging a first droplet from the nozzle so as to strike the corner from the normal direction to the top surface of the object to deposit the first droplet on the corner, and discharging a second droplet after the first droplet is dried so as to strike the corner from the normal direction to the top surface of the object at a position offset from a position of the first droplet in a direction to which the corner extends so that the second droplet partially overlaps the first droplet.

It is thereby possible to form a first coating film having a comparatively large thickness on a corner of the object. It is also possible in the first coating film formation step to form a first coating film on the corner in a simple manner, because all of the corners extending in different directions can be coated with droplets while the discharged direction of the droplets is kept constant (in the normal direction to the top surface).

In the method for forming a coating film as described above, the discharging of the first droplet preferably includes discharging the first droplet so that a center of the first droplet passes through a line segment extending from the corner in the normal direction to the top surface, and the discharging of the second droplet preferably includes discharging the second droplet so that a center of the second droplet passes through a line segment extending from the corner in the normal direction to the top surface.

The first droplet is thereby coated over the corner so as to engulf the corner. Therefore, the first droplet can be more reliably coated over the corner. Even if the position of the nozzle deviates slightly from the predetermined position or the discharge direction of the droplet deviates slightly from the normal direction to the top surface, the first droplet can still be deposited on the corner despite the deviation. The same effect is obtained with the second droplet as well.

In the method for forming a coating film as described above, the discharging of the first droplet and the discharging of the second droplet preferably include discharging the first and second droplets so that diameters of the first and second droplets are equal to each other and a distance between centers of the first and second droplets is less than the diameter of the first droplet.

It is thereby possible to further increase the film thickness of the first coating film.

In the method for forming a coating film as described above, the discharging of the first droplet preferably includes discharging a plurality of the first droplets from the nozzle so as not to overlap each other when the first droplets are deposited on the object, and the discharging of the second droplets preferably includes discharging a plurality of the second droplets from the nozzle so as not to overlap each other after the second droplets are deposited on the object.

It is thereby possible to further reduce the processing time of the first coating film formation step.

In the method for forming a coating film as described above, a diameter of the droplets is preferably in a range of 10 μm to 50 μm.

The droplets are thereby more easily deposited on the corner, and it is easier for the droplets deposited on the corner to stay on the corner (in other words, it is possible to prevent droplets from flowing down the side surface of the object due to gravity).

In the method for forming a coating film as described above, a viscosity of the droplets is preferably in a range of 10 cP to 20 cP.

The droplets thereby stay more easily on the corner.

In the method for forming a coating film as described above, the object is preferably a piezoelectric element piece made of piezoelectric material.

It is thereby possible to more easily form a resist film for forming a resist mask used when forming an electrode of a desired shape on the piezoelectric element piece, for example. Therefore, a piezoelectric element made by forming an electrode on the piezoelectric element piece can be manufactured in a simple manner.

In the method for forming a coating film as described above, the coating liquid and the coating forming material are preferably both made of a resist liquid.

It is thereby possible to more easily form a resist film for forming a resist mask used when forming an electrode of a desired shape on the piezoelectric element piece, for example. Therefore, a piezoelectric element made by forming an electrode on the piezoelectric element piece can be manufactured in a simple manner.

A method according to a second aspect is a method for manufacturing a piezoelectric element including an electrode formed on a piezoelectric element piece having a top surface, a side surface and a corner where the top and side surfaces intersect. The method includes forming a metal film on the piezoelectric element piece, forming a resist mask on a surface of the metal film, and patterning the metal film using the resist mask to form the electrode. The forming of the resist mask includes discharging droplets of a resist liquid from a nozzle to deposit the droplets on the corner of the piezoelectric element piece to form a first resist film on the corner, immersing the piezoelectric element piece in the resist liquid after the first resist film is formed on the corner of the piezoelectric element piece to form a second resist film on the top and side surfaces of the piezoelectric element piece and on the first resist film, and exposing and developing the first resist film and the second resist film to form the resist mask.

It is thereby possible to increase the film thickness of portions corresponding to the corners of a piezoelectric element piece in a resist film (an aggregate of the first and second resist films) formed on a metal film formed on the surfaces of a piezoelectric element piece. Since the first resist film is first formed on the corners of the piezoelectric element piece by a discharge method, it is easy to perceive the positions of the corners of the piezoelectric element piece, and the first resist film can be formed more accurately on the corners. Since the second resist film can be formed by immersion on the surfaces of the metal film and the first resist film after the first resist film has been formed, a resist film having a smooth surface can be formed. Therefore, unintentional removal of the metal film in the vicinity of the corners of the piezoelectric element piece can be prevented by etching the metal film via the resist mask formed by patterning the resist film. Wire snapping and short-circuiting can thereby be prevented, and a highly reliable piezoelectric element can be manufactured.

### BRIEF DESCRIPTION OF THE DRAWINGS

Referring now to the attached drawings which form a part of this original disclosure:

FIG. 1 is a perspective view showing a piezoelectric element manufactured by the method for manufacturing a piezoelectric element of the present invention;

FIG. 2 is a cross-sectional view of the piezoelectric element shown in FIG. 1 (a cross-sectional view along line A-A);

FIG. 3 includes a series of cross-sectional views showing the first embodiment of the method for manufacturing a piezoelectric element of the present invention;

FIG. 4 includes a series of cross-sectional views showing the first embodiment of the method for manufacturing a piezoelectric element of the present invention;

FIG. 5 includes a series of cross-sectional views showing the first embodiment of the method for manufacturing a piezoelectric element of the present invention;

FIG. 6 includes a series of cross-sectional views and plan view showing the method for forming a coating film according to the first embodiment of the present invention;

FIG. 7 includes a series of cross-sectional views and plan views showing the method for forming a coating film according to the first embodiment of the present invention;

FIG. 8 includes a series of cross-sectional views and plan showing the method for forming a coating film according to the first embodiment of the present invention;

FIG. 9 is a plan view showing a piezoelectric element piece on which a first resist film is formed;

FIG. 10 includes a series of cross-sectional views showing a method for forming a coating film according to the first embodiment of the present invention;

FIG. 11 includes a series of plan views showing a method for forming a coating film according to a second embodiment of the present invention;

FIG. 12 includes a series of plan views showing a method for forming a coating film according to a second embodiment of the present invention;

FIG. 13 is a plan view showing a method for forming a coating film according to a second embodiment of the present invention; and

FIG. 14 is a perspective view showing the location where the first resist film is formed in a method for forming a coating film according to the third embodiment of the present invention.

### DETAILED DESCRIPTION OF EXEMPLARY EMBODIMENTS

The method for forming a coating film and the method for manufacturing a piezoelectric element of the present invention are described in detail hereinbelow based on the embodiments shown in the accompanying drawings.

### First Embodiment

First, a description shall be provided of the first embodiment of the method for manufacturing a piezoelectric element (the method for manufacturing a piezoelectric element of the invention of the present application) comprising the method for forming a coating film of the present invention.

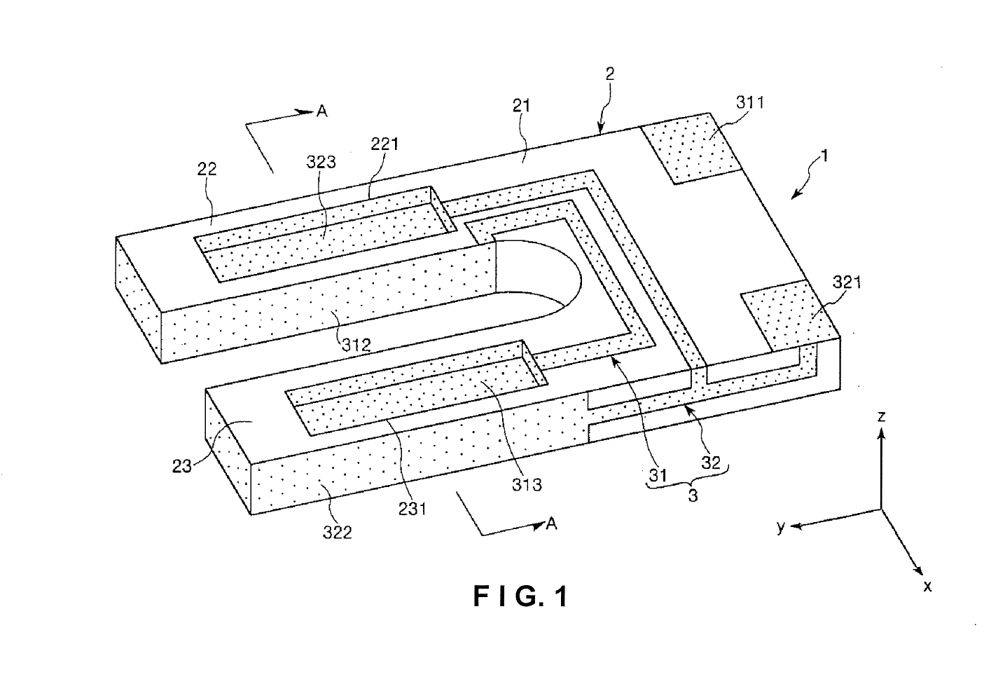

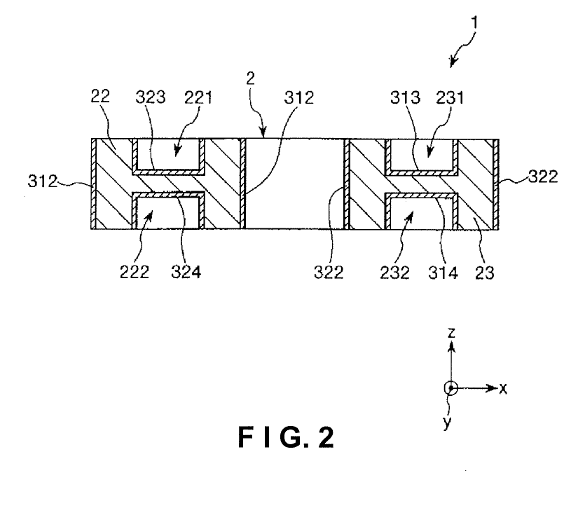

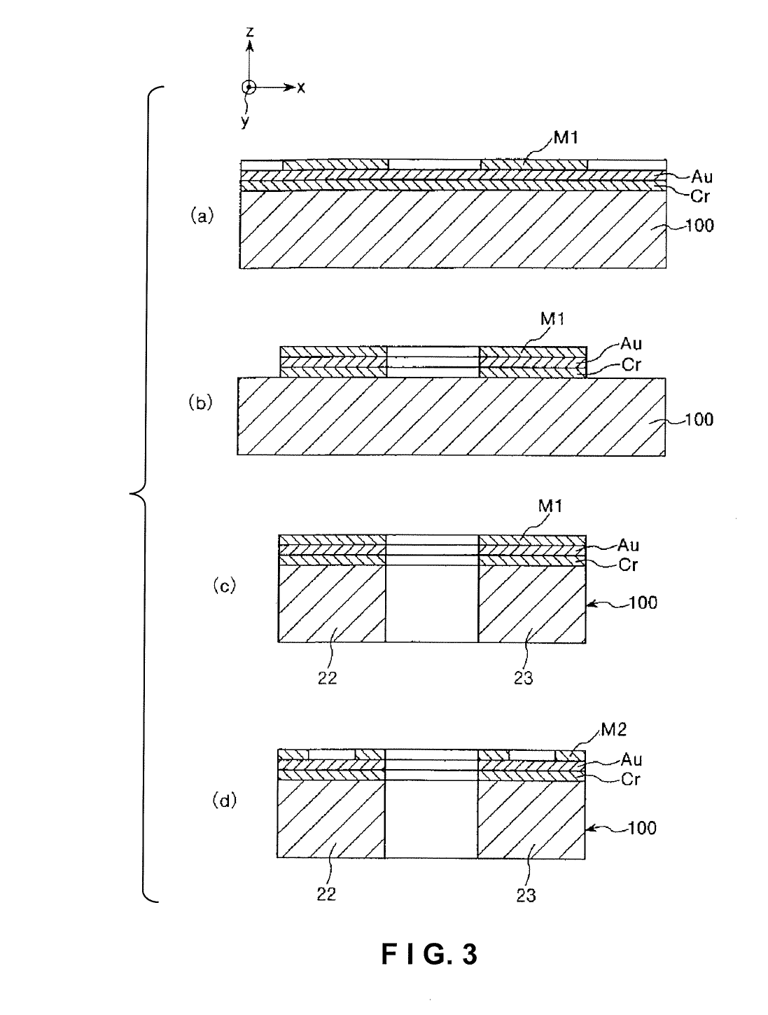

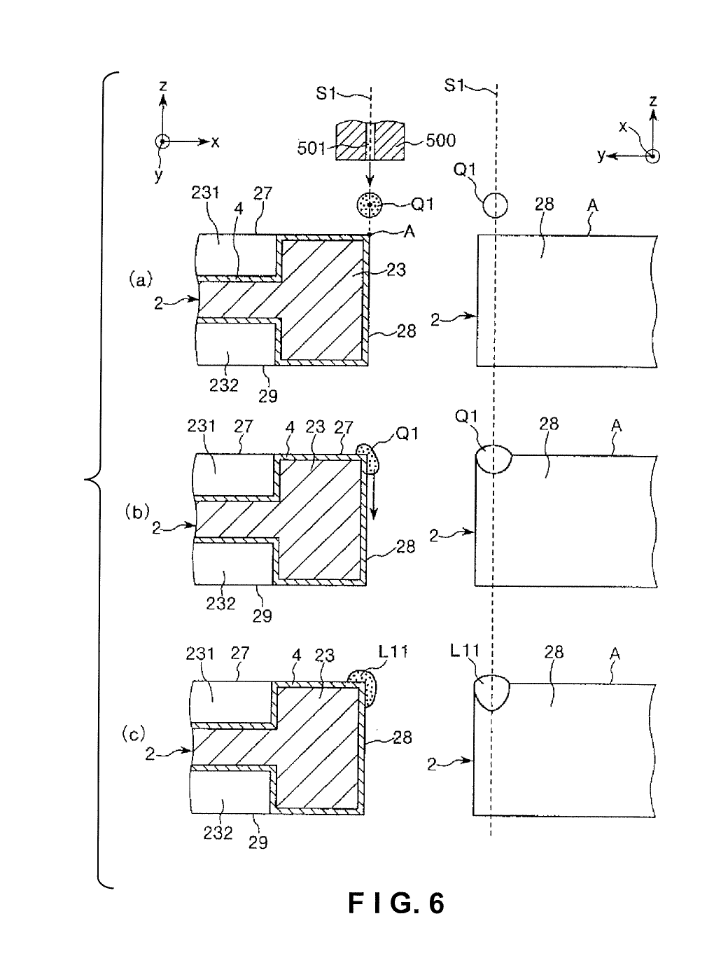

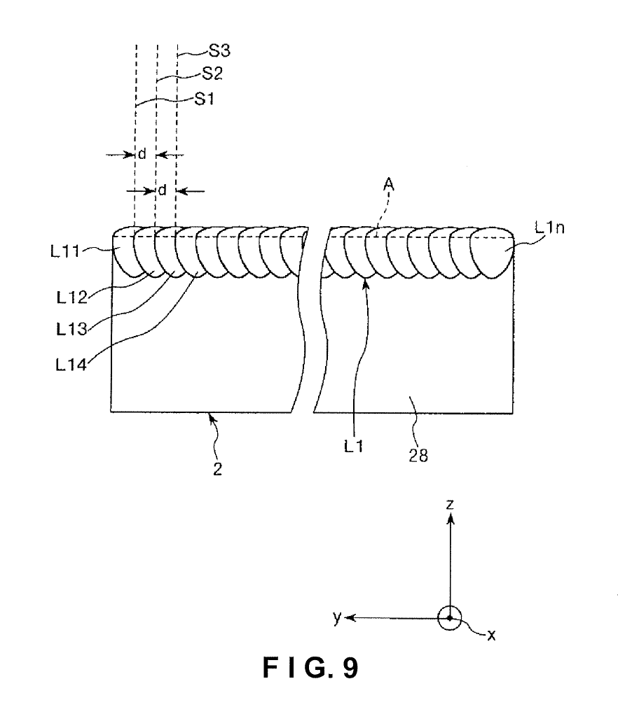

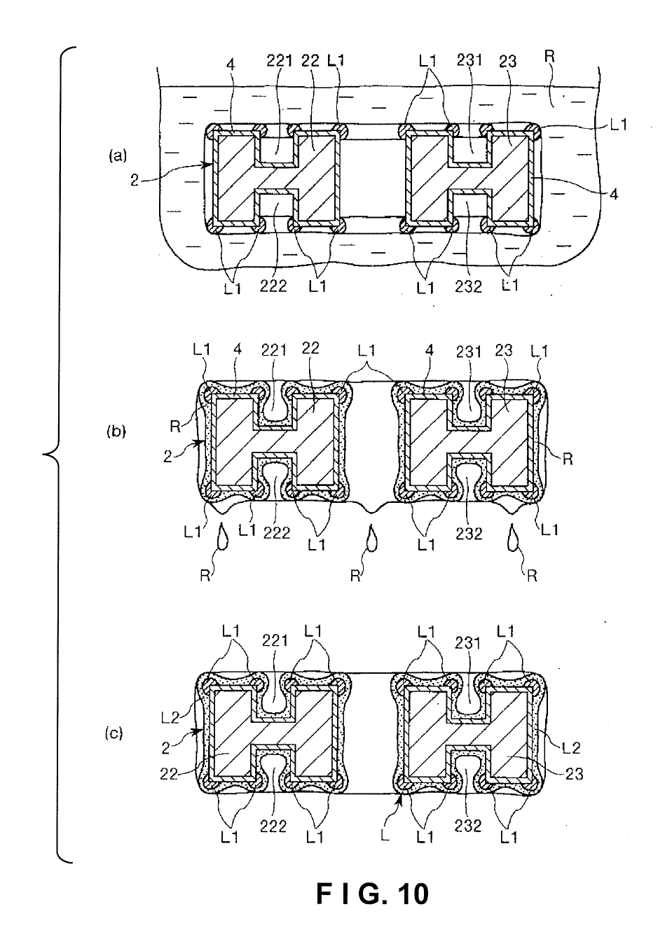

FIG. 1 is a perspective view showing a piezoelectric element manufactured by the method for manufacturing a piezoelectric element of the present invention, FIG. 2 is a cross-sectional view of the piezoelectric element shown in FIG. 1 (a cross-sectional view along line A-A), FIGS. 3 through 5 are cross-sectional views showing the first embodiment of the method for manufacturing a piezoelectric element of the present invention, FIGS. 6 through 8 are cross-sectional views and plan views showing the method for forming a coating film according to the first embodiment of the present invention, FIG. 9 is a plan view showing a piezoelectric element piece on which a first resist film is formed, and FIG. 10 is a cross-sectional view showing the method for forming a coating film according to the first embodiment of the present invention. For the sake of convenience in the following description, the top sides of FIGS. 1 through 10 are referred to as the “top,” the bottom sides as the “bottom,” the right sides as “right,” and the left sides as “left.” Hereinbelow, the three axes intersecting each other are the x-axis, the y-axis, and the z-axis, and the plane parallel to the top surface of the piezoelectric element piece 2 is the xy plane.

The piezoelectric element (oscillator) 1 shown in FIG. 1 includes a piezoelectric element piece (oscillating piece) 2 and an electrode 3 formed on the piezoelectric element piece 2.

The piezoelectric element piece (coated object) 2 is in the shape of a plate (a thin plate shape). Specifically, the piezoelectric element piece 2 has a top surface, a bottom surface, side surfaces, top corners where the top surface and side surfaces intersect, and bottom corners where the bottom surface and side surfaces intersect.

The shape of the piezoelectric element piece 2 in a plan view is that of a tuning fork. Specifically, the piezoelectric element piece 2 has a base part 21 and a pair of arm parts 22, 23 protruding from the base part 21 and extending in the same direction. A top concavity 221 opening in the top surface and a bottom concavity 222 opening in the bottom surface are formed in the arm part 22, as shown in FIG. 2. Similarly, a top concavity 231 opening in the top surface and a bottom concavity 232 opening in the bottom surface are formed in the arm part 23 as well. These concavities 221 to 232 all extend along the direction in which the arm parts 22, 23 extend. The concavities 221 to 232 also have substantially the same shape (length, width, depth, opening shape, transverse cross-sectional shape, longitudinal cross-sectional shape, and the like).

Possible examples of the material constituting this type of piezoelectric element piece 2 include crystal, zinc oxide, lead zirconate titanate, lithium niobate, lithium tetraborate, and the like. Of these examples, using crystal as the material constituting the piezoelectric element piece 2 yields a piezoelectric element 1 having excellent oscillatory characteristics, temperature characteristics, and other characteristics.

The electrode 3 has a first electrode 31 and a second electrode 32 insulated from each other, as shown in FIG. 1. The first electrode 31 has a terminal 311 formed on the top surface of the base part 21, a side surface electrode 312 formed on the side surfaces of the arm part 22 so as to encircle the side surfaces, a top concavity electrode 313 formed in the top concavity 231 of the arm part 23, and a bottom concavity electrode 314 formed in the bottom concavity 232 of the arm part 23. The side surface electrode 312 is connected to the terminal 311 via a wire formed on the side surface of the base part 21, the top concavity electrode 313 is connected to the side surface electrode 312 via a wire formed on the top surface of the base part 21, and the bottom concavity electrode 314 is connected to the side surface electrode 312 via a wire formed on the bottom surface of the base part 21.

Being symmetrical to the first electrode 31, the second electrode 32 has a terminal 321 formed on the top surface of the base part 21, a side surface electrode 322 formed on the side surfaces of the arm part 23 so as to encircle the side surfaces, a top concavity electrode 323 formed in the top concavity 221 of the arm part 22, and a bottom concavity electrode 324 formed in the bottom concavity 222 of the arm part 22. The side surface electrode 322, the top concavity electrode 323, and the bottom concavity electrode 324 are all connected to the terminal 321 via wires.

With the piezoelectric element 1 of such a configuration, for example, the base part 21 is secured in place, in which state alternating current voltages are applied to the first electrode 31 and the second electrode 32, whereby the arm parts 22, 23 are made to oscillate at a predetermined frequency, or, conversely, the electromotive force caused by the oscillation of the arm parts 22, 23 is detected by the first electrode 31 and the second electrode 32.

Next, the method for manufacturing the piezoelectric element 1 (the method for manufacturing a piezoelectric element of the present invention) will be described based on FIGS. 3 through 5. FIGS. 3 through 5 show cross-sectional views along line A-A in FIG. 1.

The method for manufacturing the piezoelectric element 1 comprises a piezoelectric element piece preparation step for preparing the piezoelectric element piece (coated object) 2, a metal film formation step for forming a metal film for forming the electrode 3 on the surface of the piezoelectric element piece 2, a resist mask formation step for forming a resist mask on the surface of the metal film, and an electrode formation step for patterning the metal film using the resist mask and forming the electrode 3. These steps are described in detail hereinbelow.

### Piezoelectric Element Piece Preparation Step

First, a crystal wafer 100 in the shape of a thin plate (e.g., a thickness of about 50 μm to 200 μm) is prepared by cutting with a saw wire or the like and then polishing and washing, and a chromium layer Cr and gold layer Au are formed in this order on the top surface of the crystal wafer 100 by sputtering, for example, as shown in FIG. 3(a). Next, after the surface of the gold layer Au is coated with a resist, the resist is subjected to lithographic exposure and image development in a pattern shaped like a tuning fork, and a resist mask M1 in the shape of a tuning fork is formed.

Next, the gold layer Au and the chromium layer Cr are etched (wet etching, dry etching, or other various etching methods can be used; the likewise hereinbelow) via the resist mask M1, and these layers are patterned into the same tuning fork shape as the resist mask M1 as shown in FIG. 3(b).

Next, the crystal wafer 100 is etched using the gold layer Au and the chromium layer Cr as masks as shown in FIG. 3(c). This yields a crystal wafer 100 having the shape of a tuning fork in a plan view, i.e., a crystal wafer having the base part 21 and the pair of arm parts 22, 23.

Next, after the resist mask M1 has been removed, the surface of the gold layer Au is again coated with a resist, the resist is subjected to lithographic exposure and image development in the pattern of the openings of the top concavities 221, 231, and a resist mask M2 is formed corresponding to the shapes of the top concavities 221, 231, as shown in FIG. 3(d).

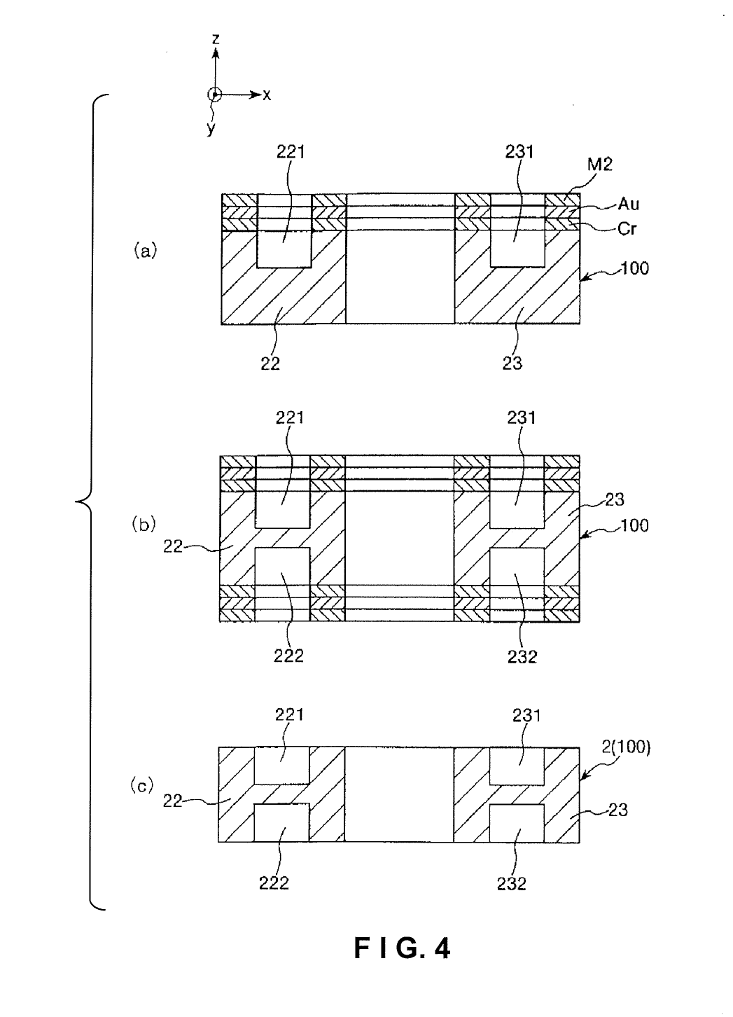

Next, the gold layer Au and the chromium layer Cr are etched via the resist mask M2, and the crystal wafer 100 is further half-etched using the gold layer Au and the chromium layer Cr as masks as shown in FIG. 4(a). Top concavities 221, 231 opening in the top surface of the crystal wafer 100 are thereby formed.

Next, the bottom concavities 222, 232 are formed by the same method by which the top concavities 221, 231 are formed, as shown in FIG. 4(b). Specifically, a chromium layer Cr and a gold layer Au are formed on the bottom surface of the crystal wafer 100, after which a resist mask having a pattern corresponding to the bottom concavities 222, 232 is formed on the surface of the gold layer Au, and the crystal wafer 100 is half-etched via the resist mask. Bottom concavities 222, 232 opening in the bottom surface of the crystal wafer 100 are thereby formed. The bottom concavities 222, 232 may be formed simultaneously with the formation of the top concavities 221, 231, or prior to the formation of the top concavities 221, 231.

Next, the entire film (the resist mask M2, the chromium layer Cr, and the gold layer Au) formed on the crystal wafer 100 is removed as shown in FIG. 4(c). The steps described above yield a piezoelectric element piece 2 having a base part 21, arm parts 22, 23, top concavities 221, 231, and bottom concavities 222, 232.

### Metal Film Formation Step

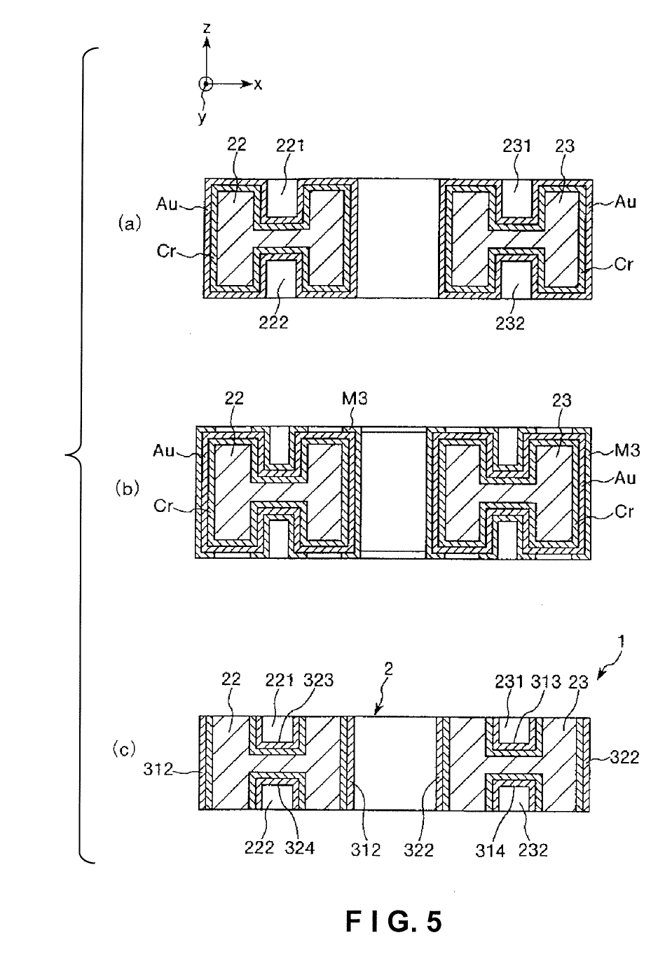

A chromium layer Cr and a gold layer Au for forming an electrode 3 (a first electrode 31 and a second electrode 32) are both formed by sputtering on the surface of the piezoelectric element piece 2 (on the top surface, the bottom surface, the side surface, and the inside surfaces of the concavities 221 to 232), as shown in FIG. 5(a).

### Resist Mask Formation Step

The surface of the gold layer Au is coated with a resist liquid by a method described hereinafter (the method for forming a coating film of the present invention), and a resist film is formed by drying the resist liquid as shown in FIG. 5(b). The resist film is then subjected to lithographic exposure and image development in the shape of the pattern of the first electrode 31 and the second electrode 32, thereby forming a resist mask M3 having the outward pattern of the first electrode 31 and the second electrode 32.

### Electrode Formation Step

The gold layer Au and the chromium layer Cr are etched via the resist mask M3, and these layers are patterned into the shape of the first and second electrodes 31, 32 as shown in FIG. 5(c). After the etching has concluded, the resist mask M3 is removed. This yields a first electrode 31 and a second electrode 32 formed by stacking of the chromium layer Cr and the gold layer Au. In order to prevent short-circuiting between the first electrode 31 and the second electrode 32, a surface protective film may be formed on the surface of the piezoelectric element piece 2 so as to cover the first electrode 31 and the second electrode 32.

The piezoelectric element 1 is manufactured by the steps described above.

After the piezoelectric element 1 has been manufactured in this manner, the frequency of the piezoelectric element 1 may be adjusted. A possible example of the adjustment method is a method in which the chromium layer Cr and the gold layer Au formed on the surface of the piezoelectric element piece 2 in the metal film formation step are used to form weighted portions on the distal end portions of the arm parts 22, 23 (on areas that do not overlap the pattern shape of the first and second electrodes 31, 32), the weighted portions are either partially or entirely removed by laser trimming, and the mass of the arm parts 22, 23 is reduced (by a mass reduction system), whereby the frequency of the piezoelectric element 1 is adjusted.

The following is a detailed description, made with reference to FIGS. 6 through 10, of the method for coating the surface of the gold layer Au with a resist in the previously described resist mask formation step. For the sake of convenience in FIGS. 6 through 8, the stacked structure of the chromium layer Cr and the gold layer Au is shown simply as an “electrode film 4” having a single-layer structure. For the sake of convenience in the following description, the component comprising the electrode film 4 formed on the surface of the piezoelectric element piece 2 is simply referred to as the “piezoelectric element piece 2.”

The resist liquid is applied to the piezoelectric element piece 2 (the formation of the resist film L) using an inkjet step (a first resist film (coating film) formation step) and a dipping step (a second resist film (coating film) formation step. These two steps are described sequentially in detail hereinbelow.

### Inkjet Step

In the inkjet step, a first resist film L1 is formed on a corner of the piezoelectric element piece 2 by an inkjet method (discharge method). Specifically, a resist liquid (droplets) Q is discharged from an inkjet head 500, and the discharged resist liquid Q is deposited on corner of the piezoelectric element piece 2, thereby forming a first resist film L1 on the corner.

An inkjet head having substantially the same configuration as those used in inkjet printers and the like can be used as the inkjet head 500. To describe the configuration of the inkjet head 500 in a simple manner, the inkjet head 500 has, for example, a nozzle plate on which a plurality of nozzle holes (e.g., two rows of fifty) is formed, a plurality of ink chambers communicating in a one-to-one ratio with the nozzle holes, and a plurality of piezo elements for compressing and expanding the ink chambers. The inkjet head is configured so that when the ink chambers are compressed and expanded by the driving of the piezo elements, the resist liquid Q filled in the ink chambers is discharged as droplets from the nozzle holes in the normal direction of the nozzle plate.

First, the piezoelectric element piece 2 is placed on a holding stand (not shown) so that the surface on the side in which the top concavities 221, 231 open (hereinbelow referred to as the “first surface 27”) is positioned on top. This non-depicted holding stand is provided with a heater or another heating means, for example, and is capable of heating the piezoelectric element piece 2 placed thereon.

The resist liquid deposited on the piezoelectric element piece 2 can be quickly dried by depositing the resist liquid on the surface of the piezoelectric element piece 2 while the piezoelectric element piece 2 is heated (kept at a predetermined temperature) by the holding stand. The time duration from the resist liquid being deposited on the piezoelectric element piece 2 to the resist liquid drying can be controlled by appropriately regulating the temperature of the piezoelectric element piece 2, for example.

Next, the first surface 27 (top surface) of the piezoelectric element 1 and the inkjet head 500 are made to face each other, and the orientation of the inkjet head 500 is set so that the nozzle plate and the first surface 27 are substantially parallel. The discharge direction of the resist liquid discharged from the inkjet head 500 thereby coincides with the normal direction of the first surface 27; i.e., with the z-axis direction.

The distance separating the nozzle plate (nozzle holes) of the inkjet head 500 and the first surface 27 at this time is not particularly limited, but is preferably about 0.5 mm to 2 mm. Such a range makes it possible to prevent contact between the inkjet head 500 and the piezoelectric element piece 2 and to deposit the resist liquid Q discharged from the nozzle holes onto the desired positions on the piezoelectric element piece 2 with high accuracy.

Next, a plurality of resist liquid droplets Q (first resist liquid droplet QR1 to nth resist liquid droplet) is deposited on the corner of the piezoelectric element piece 2, and the first resist film L1 is formed. This will be specifically described hereinbelow, but in the present embodiment, the diameters of the resist liquid droplets Q discharged from the inkjet head 500 are designed to be substantially equal.

### First Step

First, the inkjet head 500 is positioned so that a predetermined nozzle hole 501 is above a corner A where a side surface 28 and the first surface 27 intersect, as shown in FIG. 6(a). Next, a first resist liquid droplet Q1 is discharged in the z-axis direction (the normal direction of the first surface 27) from the nozzle hole 501. The discharged first resist liquid droplet Q1 is deposited on the corner A such that the center of the droplet passes through a line segment S1 extending in the z-axis direction from the corner A.

The first resist liquid droplet Q1 deposited on the corner A stays in the vicinity of the corner A as shown in FIG. 6(b). The first resist liquid droplet Q1 is then dried, forming a first resist film piece L11 on the corner A as shown in FIG. 6(c).

The position of the line segment S1 through which the center of the first resist liquid droplet Q1 passes is not particularly limited as long as the first resist liquid droplet Q1 can be deposited on the corner A, but is preferably a position that coincides with a line segment extending in the z-axis direction from the corner A. The first resist liquid droplet Q1 is thereby centered over the corner A and is coated over the corner A so as to engulf the corner. Therefore, the first resist film piece L11 can be formed more reliably on the corner A. Even if the position of the nozzle hole 501 deviates slightly from the predetermined position or the discharge direction of the first resist liquid droplet Q1 deviates slightly from the z-axis direction, the first resist liquid droplet Q1 can still be deposited on the corner A despite the deviation. The same is true for the second resist liquid droplet Q2 to the nth resist liquid droplet described hereinafter.

### Second Step

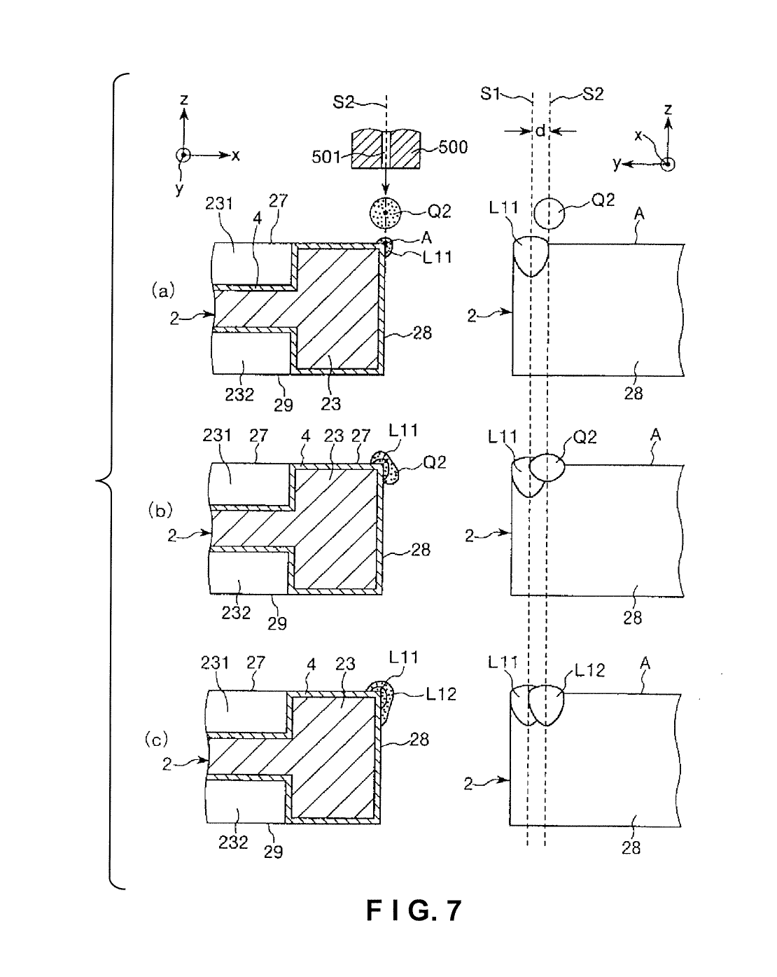

Next, the inkjet head 500 (the nozzle hole 501) is shifted a predetermined distance d in the y-axis direction (the extending direction of the corner A), and a second resist liquid droplet Q2 is discharged in the z-axis direction from the nozzle hole 501, as shown in FIG. 7(a). The center of the discharged second resist liquid droplet Q2 passes through a line segment S2 to be deposited on the corner A so that the droplet has a portion that overlaps the first resist film piece L11 when the droplet has been deposited on the piezoelectric element piece 2. The line segment S2 deviates from the line segment S1 by a predetermined distance d in the y-axis direction.

The second resist liquid droplet Q2 deposited on the corner A stays in the vicinity of the corner A as shown in FIG. 7(b). A second resist film piece L12 is formed on the corner A by drying the second resist liquid droplet Q2 as shown in FIG. 7(c). The second resist film piece L12 has an area that overlaps the first resist film piece L11, as shown in FIG. 7(c).

### Third Step

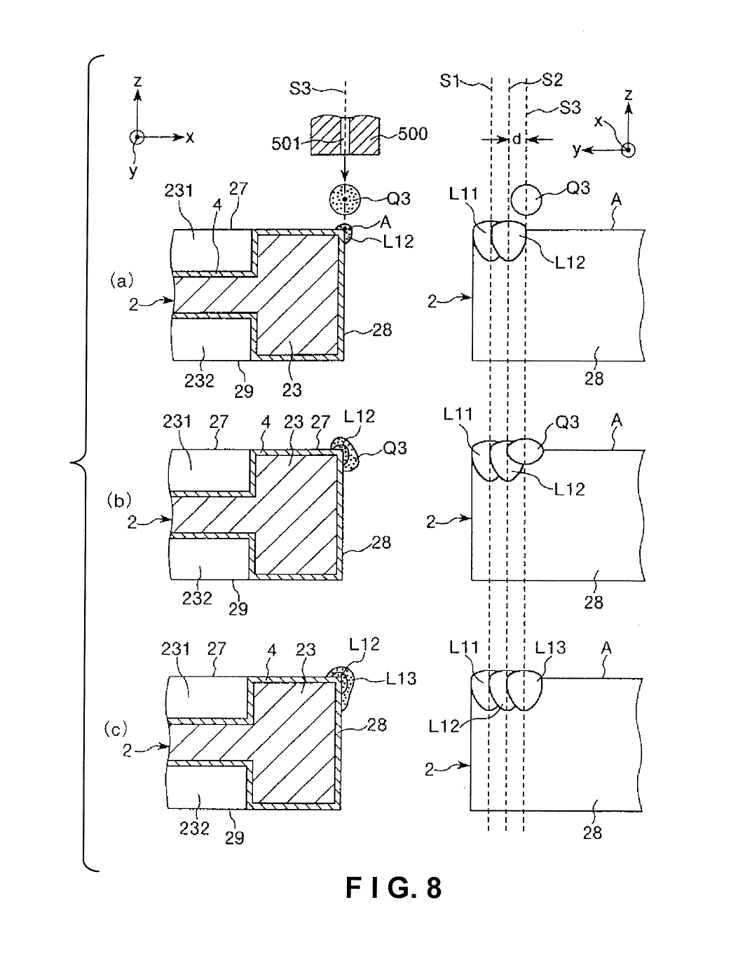

Next, the inkjet head 500 is shifted a predetermined distance d in the y-axis direction, and a third resist liquid droplet Q3 is discharged in the z-axis direction from the nozzle hole 501 as shown in FIG. 8(a). The discharged third resist liquid droplet Q3 passes through a line segment S3 to be deposited on the corner A so that the droplet has a portion that overlaps the second resist film piece L12 when the droplet has been deposited on the piezoelectric element piece 2. The line segment S3 deviates from the line segment S2 by a predetermined distance d in the y-axis direction.

The third resist liquid droplet Q3 deposited on the corner A stays in the vicinity of the corner A as shown in FIG. 8(b). A third resist film piece L13 is formed on the corner A by drying the third resist liquid droplet Q3 as shown in FIG. 8(c). The third resist film piece L13 has an area that overlaps the second resist film piece L12, as shown in FIG. 8(c).

### Fourth Step to Nth Step

A fourth resist film piece L14 to an nth resist film piece L1n are formed on the corner A by the same method by which the first resist film piece L11 to the third resist film piece L13 are formed on the corner A as described above. This yields a first resist film L1 (a combination of the first resist film piece L11 to the nth resist film piece L1n) formed over the entire corner A as shown in FIG. 9.

A first resist film L1 is also formed on the other corners positioned on the first surface 27 (e.g., corners such as the ones where the inside surfaces of the top concavities 221, 231 and the first surface 27 intersect) in the same manner in which the first resist film L1 was formed on this corner A.

Thus ends in the manner described above for the formation of a first resist film L1 on the corners positioned on the first surface 27 side of the piezoelectric element piece 2.

Next, the piezoelectric element piece 2 is turned upside-down, and a first resist film L1 is formed on the corners positioned on the second surface 29 side of the piezoelectric element piece 2 (such as the corner where the side surface 28 and the second surface 29 intersect, and the corners where the inside surfaces of the bottom concavities 222, 232 and the second surface 29 intersect). The method for forming the first resist film L1 on the corners on the second surface 29 side is the same as the method for forming the first resist film L1 on the corners on the first surface 27 side previously described, and is therefore not described herein.

The inkjet step (the first resist film formation step) thereby concludes.

Thus, the first resist film L1 is formed on the corners of the piezoelectric element piece 2 by the inkjet step prior to the dipping step, whereby the inkjet step can be performed in a state in which the corners of the piezoelectric element piece 2 are exposed. Therefore, the positions of the corners of the piezoelectric element piece 2 are easily perceived, and the resist liquid Q can be accurately deposited on the corners of the piezoelectric element piece 2. Therefore, the first resist film L1 can be formed accurately on the corners.

In this inkjet step, since the first resist film L1 is formed by drying the resist liquid Q (the first resist liquid droplet Q1 to the nth resist liquid droplet) that has stopped on the corners of the piezoelectric element piece 2, the film thickness of the first resist film L1 can be made comparatively thick.

In this inkjet step, the resist liquid Q can be coated over all of the corners extending in different directions while the orientation of the inkjet head 500 relative to the piezoelectric element piece 2 remains constant. Therefore, the formation of the first resist film L1 can be simplified.

Particularly, in the present embodiment, since adjacent resist film pieces (e.g., the first and second resist film pieces L11, L12) are formed so as to overlap each other, the first resist film L1 can have a configuration in which a plurality of resist film pieces overlap (a stacked configuration). Therefore, the film thickness of the first resist film L1 can be increased.

For such reasons, the distance (predetermined distance d) between the centers of a pair of resist liquid droplets Q whose discharged positions from the nozzle hole 501 are adjacent is preferably a distance whereby the pair of resist liquid droplets Q can overlap after having been deposited on the piezoelectric element piece 2.

Of these distances, it is particularly preferable that the predetermined distance d be a distance smaller than the diameter of deposited droplets of resist liquid Q. It is thereby possible to prevent the film thickness of the first resist film L1 from becoming too great, and to reduce the amount of resist liquid Q used.

The diameter of the resist liquid droplets Q is not particularly limited, but is preferably about 10 μm to 50 μm. 15 μm to 25 μm is even more preferred. A resist liquid droplet Q diameter of this size makes it easier to deposit the resist liquid Q on the corners of the piezoelectric element piece 2, and also makes it easier for the resist liquid Q to stay on the corners. In other words, it is possible to prevent the resist liquid Q from flowing down the side surface 28 due to gravity and thereby reducing the film thickness of the first resist film L1.

The viscosity of the resist liquid Q is not particularly limited, but is preferably about 1 cP to 20 cP (0.001 Pa·s to 0.02 Pa·s). This makes it possible for the resist liquid Q to be more accurately deposited and stay on the corners of the piezoelectric element piece 2.

### Dipping Step

In the present step, a second resist film L2 is formed on the surfaces of the piezoelectric element piece 2 and the first resist film L1. In the present step, a container is filled with a dipping resist liquid (resist liquid for immersion, coating liquid for immersion) R, and the piezoelectric element piece 2 on which the first resist film L1 is formed is then immersed in the dipping resist liquid R as shown in FIG. 10(a).

Next, the piezoelectric element piece 2 is removed from the dipping resist liquid R, and excess (extra) dipping resist liquid R adhering to the piezoelectric element piece 2 is removed using centrifugal force or the like, for example, as shown in FIG. 10(b). Next, the dipping resist liquid R coated over the surface of the piezoelectric element piece 2 is dried, thereby forming a second resist film L2 as shown in FIG. 10(c).

The dipping step is thereby ended.

Thus, a resist film L having a smooth surface can be formed by forming a first resist film L1 by an inkjet method, and then forming a second resist film L2 on the surfaces of the piezoelectric element piece 2 and the first resist film L1 by a dipping method.

The viscosity of the dipping resist liquid R used in the present step is not particularly limited, but is preferably a comparatively low viscosity. Specifically, it is preferably about 1 cP to 100 cP, for example. It is thereby possible to improve the adhesiveness of the dipping resist liquid R relative to the piezoelectric element piece 2 and the first resist film L1, and to prevent the film thickness of the dipping resist liquid R coated over the piezoelectric element piece 2 from becoming too great.

The first resist film L1 and the second resist film L2 are formed on the piezoelectric element piece 2 via the inkjet step and the dipping step described above, and a resist film L made of these first and second resist films L1, L2 is obtained. With this resist film L, the film thickness of the portions corresponding to the corners of the piezoelectric element piece 2 can be increased by the presence of the first resist film L1. Therefore, the entire resist film L can have a thickness sufficient to exhibit the function of the resist mask M3, i.e., a thickness sufficient to withstand etching.

Therefore, when the electrode film 4 is etched via the resist mask M3 in the previously described electrode formation step, it is possible to prevent the electrode film 4 from being unintentionally removed in the vicinity of the corners (e.g., the corner A) of the piezoelectric element piece 2. As a result, wire snapping, short-circuits, and other problems in the electrode 3 can be prevented, and a highly reliable piezoelectric element 1 can be manufactured.

After a resist film L made of the first resist film L1 and the second resist film L2 is formed on the piezoelectric element piece 2 by the first resist film formation step and the second resist film formation step described above, a resist mask M3 having the same outward pattern as the first and second electrodes 31, 32 can be formed by subjecting the resist film L to lithographic exposure and image development in the shape of the pattern of the first electrode 31 and the second electrode 32.

### Second Embodiment

The following is a description of a second embodiment of the method for manufacturing a piezoelectric element comprising the method for forming a coating film of the present invention (the method for manufacturing a piezoelectric element of the invention of the present application).

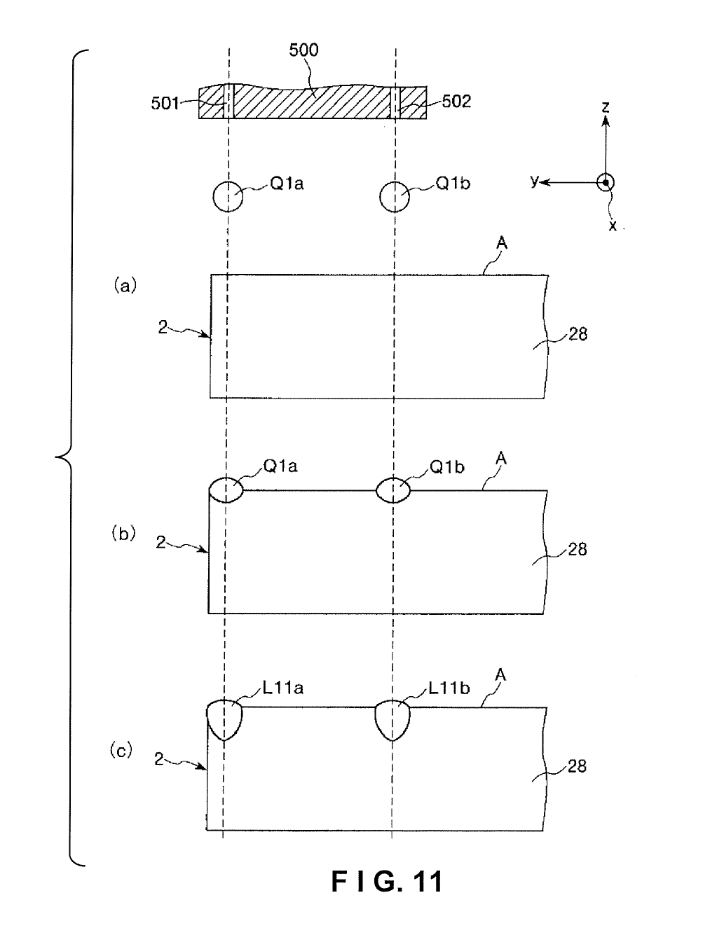

FIGS. 11 through 13 are plan views showing the method for forming a coating film according to the second embodiment of the present invention.

The method for manufacturing a piezoelectric element of the second embodiment is described hereinbelow with a focus on the differences from the embodiment previously described, and similar concepts are not described herein.

The method for manufacturing a piezoelectric element according to the second embodiment of the present invention is similar to the first embodiment previously described except for a difference in the inkjet step (the first resist film formation step). Components similar to those of the first embodiment previously described are denoted by the same symbols.

### Inkjet Step

### First Step

First, first resist liquid droplets Q1a, Q1b are discharged from two nozzle holes 501, 502 of the inkjet head 500, the nozzle holes being separated from each other in the y-axis direction, and these first resist liquid droplets Q1a, Q1b are deposited on a corner A of the piezoelectric element piece 2, as shown in FIG. 11(a). The first resist liquid droplets Q1a, Q1b are sufficiently separated so as not to overlap each other after having been deposited on the piezoelectric element piece 2, as shown in FIG. 11(b). First resist film pieces L11a, L11b separated from each other are formed on the corner A by drying the first resist liquid droplets Q1a, Q1b, as shown in FIG. 11(c).

### Second Step

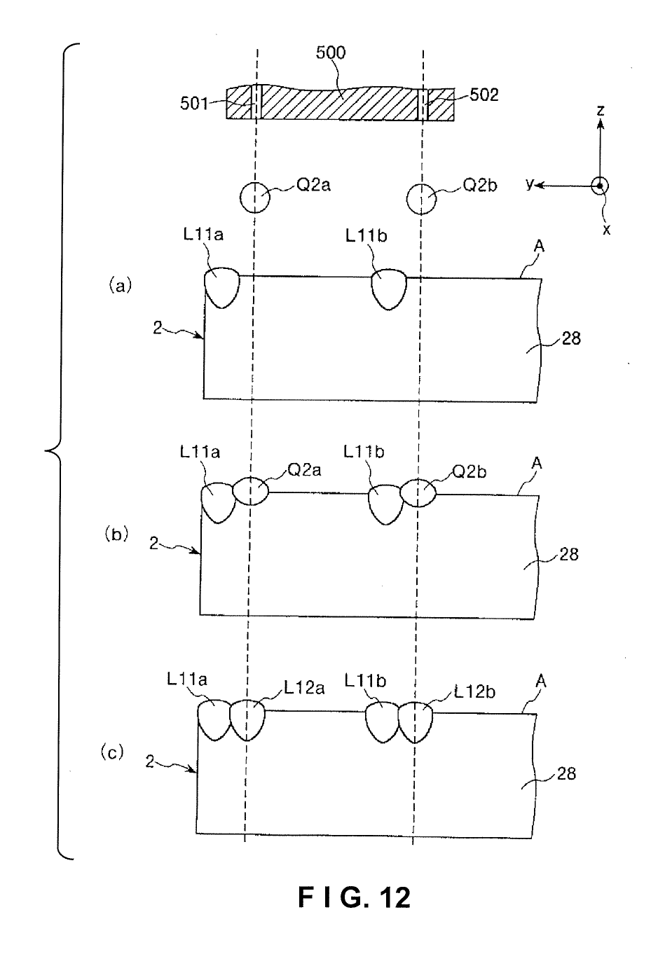

Next, the inkjet head 500 is shifted a predetermined distance d in the y-axis direction, and second resist liquid droplets Q2a, Q2b are discharged at substantially the same time in the z-axis direction as shown in FIG. 12(a). The discharged second resist liquid droplet Q2a is deposited on the corner A so as to have a portion overlapping the first resist film piece L11a after having been deposited on the piezoelectric element piece 2, and at the same time, the second resist liquid droplet Q2b is deposited on the corner A so as to have a portion overlapping the first resist film piece L11b after having been deposited on the piezoelectric element piece 2, as shown in FIG. 12(b). The second resist liquid droplets Q2a, Q2b are then dried, thereby forming second resist film pieces L12a, L12b separated from each other on the corner A as shown in FIG. 12(c).

### Third Step to nth Step

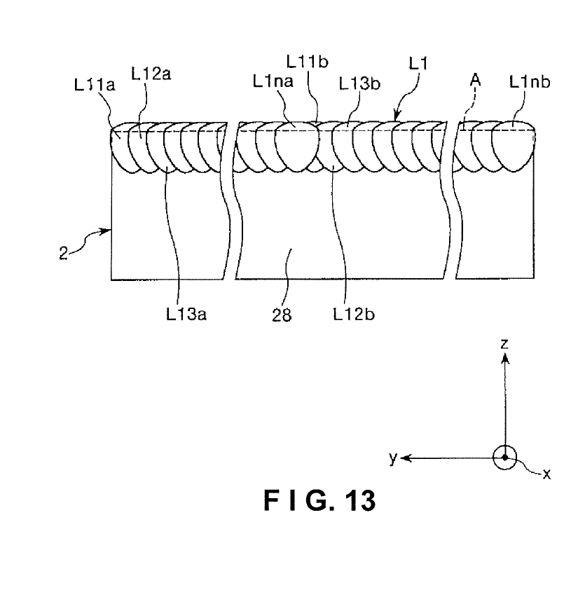

Third resist film pieces L13a, L13b to nth resist film pieces L1na, L1nb are formed on the corner A in the same manner in which the first resist film pieces L11a, L11b and the second resist film pieces L12a, L12b were formed on the corner A as described above. It is thereby possible to obtain a first resist film L1 formed over the entire corner A as shown in FIG. 13.

The first resist film L1 is formed in the same manner on the other corners.

According to this type of inkjet step, a plurality of resist film pieces is formed simultaneously in the steps (the first step to the nth step), and it is therefore possible for the steps to require less time (processing time) than the inkjet step of the first embodiment, for example.

The same effects as the first embodiment can also be exhibited through the second embodiment described above.

### Third Embodiment

The following is a description of a third embodiment of the method for manufacturing a piezoelectric element comprising the method for forming a coating film of the present invention (the method for manufacturing a piezoelectric element of the invention of the present application).

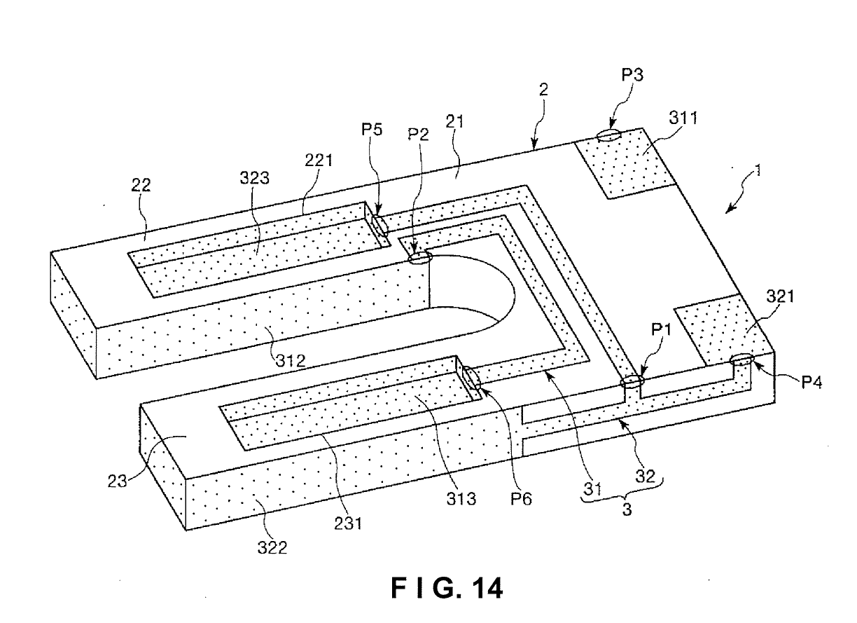

FIG. 14 is a perspective view showing the locations where the first resist film is formed in the method for forming a coating film according to the third embodiment of the present invention.

The method for manufacturing a piezoelectric element of the third embodiment is described hereinbelow with a focus on the differences from the embodiments previously described, and similar concepts are not described herein.

The method for manufacturing a piezoelectric element according to the third embodiment of the present invention is similar to the first embodiment previously described except for a difference in the inkjet step (the first resist film formation step). Components similar to those of the first embodiment previously described are denoted by the same symbols.

The inkjet step of the present embodiment is configured so that the first resist film L1 is formed only on the necessary portions of the corners, rather than the first resist film L1 being formed entirely on all of the corners (the corner A and others) of the piezoelectric element piece 2.

Specifically, it is possible to form a highly reliably piezoelectric element 1 wherein wire snapping and other problems are prevented if unintentional removal of the electrode film 4 can be prevented at least in locations where wires are formed on the corners of the piezoelectric element piece 2, i.e., locations where wires are formed over corners where the top surface and the side surfaces intersect, such as P1 through P4 in FIG. 14; locations where wires are formed over corners where the top surface and the inside surfaces of the top concavities 221, 231 intersect, such as P5 and P6; locations (not shown) where wires are formed over corners where the bottom concavities 222, 232 and the bottom surface intersect; and other locations.

Therefore, in the present embodiment, the first resist film L1 is formed on the corners of the piezoelectric element piece 2 only in locations where wires are required to be formed on the corners of the piezoelectric element piece 2, such as those described above. It is thereby possible to forgo forming the first resist film L1 on unnecessary portions of the corners, to reduce the time duration in which the inkjet step is performed, and to reduce the amount of resist liquid R used.

The same effects as the first embodiment can also be exhibited through the third embodiment described above.

The method for forming a coating film and the method for manufacturing a piezoelectric element of the present invention were described above based on illustrated embodiments, but the present invention is not limited to these embodiments, and the configurations of all components can be replaced by any desired configurations having the same functions. Any other desired configurations or steps may also be added.

In the embodiments previously described, a configuration was described in which a resist liquid for forming a resist film was used as the coating liquid for immersion and the droplets, but the droplets for immersion and the droplets are not limited to this option alone, and may be insulative droplets for immersion and droplets for forming an insulated film, or electroconductive droplets for immersion and droplets for forming an electrode film or wiring film.

In the embodiments previously described, a configuration using a piezoelectric substrate made of piezoelectric material was described as the coated object, but the coated object is not limited to this option alone, and may be, for example, a resin substrate (synthetic resin substrate) made of various resin materials, a metal substrate made of Au, Ag, Cu, Fe, or other various metal materials, a ceramic substrate made of various ceramics, a silicon substrate or another semiconductor substrate, a glass substrate made of quartz glass and other various glass materials, a sapphire substrate, a diamond substrate, or the like.

The shape of the piezoelectric element piece was described as that of a tuning fork having two arm parts, but the shape is not limited to this option alone, and may be an “addorsed E” shape having six arm parts (i.e., three arms extending in one direction and three arms extending in the opposite direction form a center part) used in a gyro sensor or the like, for example.

### General Interpretation of Terms

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Finally, terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

What is claimed is:

1. A method for forming a coating film on an object having a top surface, a side surface, and a corner where the top and side surfaces intersect, the method comprising:
discharging droplets of coating forming material from a nozzle to deposit the droplets on the corner of the object to form a first coating film on the corner; and
immersing the object in an immersion coating liquid after the first coating film is formed on the corner of the object to form a second coating film on the top and side surfaces of the object and on the first coating film.

2. The method for forming a coating film according to claim 1, wherein
the discharging of the droplets includes selectively forming the first coating film on a prescribed portion of the corner.

3. The method for forming a coating film according to claim 1, wherein
the discharging of the droplets includes
discharging a first droplet from the nozzle so as to strike the corner from the normal direction to the top surface of the object to deposit the first droplet on the corner, and
discharging a second droplet after the first droplet is dried so as to strike the corner from the normal direction to the top surface of the object at a position offset from a position of the first droplet in a direction to which the corner extends so that the second droplet partially overlaps the first droplet.

4. The method for forming a coating film according to claim 3, wherein
the discharging of the first droplet includes discharging the first droplet so that a center of the first droplet passes through a line segment extending from the corner in the normal direction to the top surface, and
the discharging of the second droplet includes discharging the second droplet so that a center of the second droplet passes through a line segment extending from the corner in the normal direction to the top surface.

5. The method for forming a coating film according to claim 3, wherein
the discharging of the first droplet and the discharging of the second droplet include discharging the first and second droplets so that diameters of the first and second droplets are equal to each other and a distance between centers of the first and second droplets is less than the diameter of the first droplet.

6. The method for forming a coating film according to claim 3, wherein
the discharging of the first droplet includes discharging a plurality of the first droplets from the nozzle so as not to overlap each other when the first droplets are deposited on the object, and
the discharging of the second droplets includes discharging a plurality of the second droplets from the nozzle so as not to overlap each other after the second droplets are deposited on the object.

7. The method for forming a coating film according to claim 1, wherein a diameter of the droplets is in a range of 10 μm to 50 μm.

8. The method for forming a coating film according to claim 1, wherein
a viscosity of the droplets is in a range of 10 cP to 20 cP.

9. The method for forming a coating film according to claim 1, wherein
the object is a piezoelectric element piece made of piezoelectric material.

10. The method for forming a coating film according to claim 1, wherein
the coating liquid and the coating forming material are both made of a resist liquid.

11. A method for manufacturing a piezoelectric element including an electrode formed on a piezoelectric element piece having a top surface, a side surface and a corner where the top and side surfaces intersect, the method comprising:
forming a metal film on the piezoelectric element piece;
forming a resist mask on a surface of the metal film; and
patterning the metal film using the resist mask to form the electrode,
the forming of the resist mask including
discharging droplets of a resist liquid from a nozzle to deposit the droplets on the corner of the piezoelectric element piece to form a first resist film on the corner,
immersing the piezoelectric element piece in the resist liquid after the first resist film is formed on the corner of the piezoelectric element piece to form a second resist film on the top and side surfaces of the piezoelectric element piece and on the first resist film, and
exposing and developing the first resist film and the second resist film to form the resist mask.
